(19) United States
(12) Patent Application Publication
(10) Pub. No.: US 2015/0083465 A1
(43) Pub. Date: Mar. 26, 2015

(54) TRANSPARENT CONDUCTIVE SUBSTRATE, AND METHOD FOR MANUFACTURING SAME

(71) Applicants: Jung Heum Yun, Gyeongsangnam-do (KR); Gun Hwan Lee, Gyeonggi-do (KR); Yeon Hyun Park, Busan (KR); Sung Hun Lee, Gyeongsangnam-do (KR)

(72) Inventors: Jung Heum Yun, Gyeongsangnam-do (KR); Gun Hwan Lee, Gyeonggi-do (KR); Yeon Hyun Park, Busan (KR); Sung Hun Lee, Gyeongsangnam-do (KR)

(73) Assignee: KOREA INSTITUTE OF MACHINERY & MATERIALS, Daejeon (KR)

(21) Appl. No.: 14/398,424

(22) PCT Filed: May 7, 2012
(86) PCT No.: PCT/KR2012/003553

§ 371 Date: Oct. 31, 2014

(51) Int. Cl. H05K 1/02; H05K 3/28; H05K 3/00

(52) U.S. Cl. CPC H05K 1/0274; H05K 3/0041; H05K 3/28; H05K 2201/2054; H05K 2201/10977; H05K 2201/0326; H05K 2201/015
USPC 174/251; 216/11

(57) ABSTRACT

A transparent or conductive substrate and its manufacturing method are provided. The transparent or conductive substrate comprises a base substrate capable of light transmission; a transparent electroconductive layer formed by depositing a transparent electroconductive material; and an anti-reflection layer, wherein the anti-reflection layer is formed by using a dry etching method and comprises a plurality of spine-type structures and an anti-reflection structure formed by depositing inorganic particles.

### BACKGROUND OF THE INVENTION

1. Technology Field

The present invention relates to a transparent or conductive substrate and its manufacturing method.

2. Description of the Related Art

Recently, touch screens have been applied to numerous portable electronic devices such as mobile phones, smartphones, tablet PCs and so on. Use of EL back lights, electromagnetic proctors, solar cells and so on along with the touch screens increases use of polymer-based transparent or conductive substrates.

The polymer-based transparent or conductive substrate is a substrate having a transparent electroconductive layer coated on a polymer base substrate which thus not only has transparent and optical effects but also is capable of being electrified.

Thus, there is a large demand for the polymer-based transparent or conductive substrate having electrical conductivity and high optical transparency. However, so far it has been still difficult to provide both electrical conductivity and optical transparency at the same time.

KR Patent Publication No. 2011-0136514 (2011. 12. 21) discloses “unit cells of dye-sensitized solar cell and preparation method for dye-sensitized solar cell module using them”.

### SUMMARY OF THE INVENTION

An object of the present invention is to provide a transparent or conductive substrate having electrical properties and optical properties at the same time.

Another object of the present invention is to provide a transparent or conductive substrate having fingerprint prevention properties.

Further another object of the present invention is to provide a transparent or conductive substrate blocking penetration of foreign materials and protecting the substrate from the outside environment.

According to an aspect of the present invention, there is provided a method for manufacturing a transparent or conductive substrate comprising: preparing a base substrate capable of light transmission; forming a transparent electroconductive layer by depositing a transparent electroconductive material on a first side of the base substrate; and forming an anti-reflection layer on a second side of the base substrate, wherein the step of forming an anti-reflection layer comprises: forming a plurality of spine-type structures on the second side of the base substrate using a dry etching method; and forming an anti-reflection structure preventing light reflection on the plurality of spine-type structures by depositing inorganic particles.

According to another aspect of the present invention, there is provided a method for manufacturing a transparent or conductive substrate comprising: preparing a base substrate capable of light transmission; and forming a conductive anti-reflection layer on a first side of the base substrate, wherein the step of forming a conductive anti-reflection layer comprises: forming a plurality of spine-type structures on the first side of the base substrate using a dry etching method; and forming an anti-reflection transparent electroconductive layer on the plurality of spine-type structures by depositing a transparent electroconductive material.

Preferably, the anti-reflection transparent electroconductive layer may comprise a continuous conducting layer which is formed by depositing the transparent electroconductive material; and a conductive anti-reflection structure.

The base substrate may comprise a reinforced coating layer.

The base substrate may comprise at least one selected from a fluorinated transparent polymer film, an acrylic transparent polymerfilm, a polyethylene terephthalate transparent polymer film, a polycarbonate, polyethylene naphthalate, a polyethersulfone, a polycycloolefin, a CR39 and a polyiourethane.

The transparent electroconductive material may be an oxide comprising at least one selected from Zn, Cd, In, Ga, Sig and Ti.

The transparent electroconductive material may be deposited by sputtering method.

The plurality of spine-type structures may be formed by using a plasma etching method or an ion-beam etching method.

Array spacing of the plurality of spine-type structures may be adjusted by controlling etching exposure time.

The etching exposure time may be less than 7 minutes.

The anti-reflection structure or the conductive anti-reflection structure may be formed by arranging adjacent to each other.

The anti-reflection structure or the conductive anti-reflection structure may be spherical shape.

The anti-reflection layer may further comprise a continuous layer formed by depositing the inorganic particles between the plurality of spine-type structures and the anti-reflection structures.

The anti-reflection structure may be formed by a plasma thin film deposition of the inorganic particles.

The inorganic particles may comprise at least one of metal oxides and metal nitrides of Al, Ba, Be, Ca, Cr, Cu, Cd, Dy, Ga, Ge, Hf, In, Lu, Mg, Mo, Ni, Rb, Sc, Si, Sn, Ta, Te, Ti, W, Zn, Zr, and Yb, and magnesium fluoride.

The anti-reflection structure may be arranged at intervals of 200 nm or less.

Preferably, the method for manufacturing a transparent or conductive substrate may further comprise forming a continuous thin layer on the anti-reflection layer.

The step of forming a continuous thin layer may use the same inorganic particles.

Preferably, the method for manufacturing a transparent or conductive substrate may further comprise forming a fingerprint prevention layer on the anti-reflection layer.

Preferably, the method for manufacturing a transparent or conductive substrate may further comprise forming a fingerprint prevention layer on the continuous thin layer.

The fingerprint prevention layer may be forced by comprising at least one of a methyl group (CH3) and a fluorocarbon group (CF).

The fingerprint prevention layer may be formed by depositing at least one selected from cyclomethicone(C₈H₂₄Si₄O₄), hexamethyldisiloxane(HMDSO), octamethylcyclotetrasiloxane(OMICTS), 2-fluoro-6-methoxybenzaldehyde, 3-fluoro-4-methoxybenzaldehyde, 4-fluoro-3-methoxybenzaldehyde, 5-fluoro-2-methoxybenzaldehyde, 2-fluoro-6-methoxyphenol, 4-fluoro-2-methoxyphenol and 5-fluoro-3-methoxysalicylaldehyde.

Preferably, the method for manufacturing a transparent or conductive substrate may further comprise forming a protection layer on the second side of the base substrate.

The protection layer may be formed by comprising at least one of oxides of Si, Al, Zn and Ti.

Preferably, the method for manufacturing a transparent or conductive substrate may further comprise forming an anti-reflection layer on the second side of the base substrate.

Preferably, the step of forming an anti-reflection layer may comprise forming a plurality of spine-type structures on the second side of the base substrate by using a dry etching method; and forming an anti-reflection structure capable of preventing light reflection on the plurality of spine-type structures by depositing inorganic particles.

Preferably, the method for manufacturing a transparent or conductive substrate may further comprise forming a continuous thin layer on the anti-reflection layer.

Preferably, the method for manufacturing a transparent or conductive substrate may further comprise forming a fingerprint prevention layer on the anti-reflection layer.

Preferably, the method for manufacturing a transparent or conductive substrate may further comprise forming a fingerprint prevention layer on the continuous thin layer.

According to further another aspect of the present invention, there is provided a transparent or conductive substrate comprising: a base substrate capable of light transmission; a transparent electroconductive layer formed by depositing a transparent electroconductive material on a first side of the base substrate; and an anti-reflection layer formed on a second side of the base substrate, wherein the anti-reflection layer comprises: a plurality of spine-type structures on the second side of the base substrate using a dry etching method; and an anti-reflection structure formed on the plurality of spine-type structures by depositing inorganic particles.

According to further another aspect of the present invention, there is provided a transparent or conductive substrate comprising: a base substrate capable of light transmission; and a conductive anti-reflection layer formed on a first side of the base substrate, wherein the conductive anti-reflection layer comprises; a plurality of spine-type structures formed on the first side of the base substrate using a dry etching method; and an anti-reflection transparent electroconductive layer formed on the plurality of spine-type structures by depositing a transparent electroconductive material.

Preferably, the anti-reflection transparent eiectroconductive layer may comprise a continuous conducting layer formed by depositing the transparent electroconductive material; and a conductive anti-reflection structure preventing light reflection.

Preferably, the transparent or conductive substrate may further comprise a continuous thin layer formed on the anti-reflection layer.

Preferably, the transparent or conductive substrate may further comprise a fingerprint prevention layer formed an the anti-reflection layer.

Preferably, the transparent or conductive substrate may further comprise a fingerprint prevention layer formed on the continuous thin layer.

Preferably, the transparent or conductive substrate may further comprise a protection layer on the second side of the base substrate.

Preferably, the transparent or conductive substrate may further comprise an anti-reflection layer on the second side of the base substrate.

Preferably, the anti-reflection layer may comprise a plurality of spine-type structures formed on the second side of the base substrate by using a dry etching method, and an anti-reflection structure formed on the plurality of spine-type structures by depositing inorganic particles.

Preferably, the transparent or conductive substrate may further comprise a continuous thin layer formed on the anti-reflection layer.

Preferably, the transparent or conductive substrate may further comprise a fingerprint prevention layer formed on the anti-reflection layer.

Preferably, the transparent or conductive substrate may further comprise a fingerprint prevention layer formed on the continuous thin layer.

The present invention allows easy control of optical properties and physical properties of a transparent or conductive substrate.

In addition, the transparent or conductive substrate of the present invention provides water repellency which is function not to absorb water but to let water flow down when water is applied and anti-fingerprint property preventing user's fingerprints.

In addition, the transparent or conductive substrate of the present invention protects the base substrate and strengthens the hardness of the substrate.

### BRIEF DESCRIPTION OF THE DRAWINGS

FIG. 1 is a diagram illustrating a transparent or conductive substrate according to an embodiment of the present invention.

FIG. 2 illustrates an actual structure of an anti-reflection layer according to an embodiment of the present invention.

FIG. 3 is a graph illustrating transmittances of an anti-reflection layer according to an embodiment of the present invention as a function of etching exposure time.

FIG. 4 is a graph illustrating actual distances of an anti-reflection structure according to an embodiment of the present invention as a function of etching exposure time.

FIG. 5 illustrates an anti-reflection structure arranged adjacent to each other according to an embodiment of the present invention.

FIG. 6 illustrates durabilities of a transparent or conductive substrate according to an embodiment of the present invention,

FIG. 7 illustrates durabilities of a conventional transparent or conductive substrate.

FIG. 8 illustrates a transparent or conductive substrate according to another embodiment of the present invention.

FIG. 9 illustrates an acture structure of a conductive anti-reflection layer according to an embodiment of the present invention.

FIG. 10 is a graph illustrating transmittances of an anti-reflection transparent electroconductive layer according to an embodiment of the present invention as a function of thickness.

FIG. 11 is a graph illustrating transmittances of a conductive anti-reflection layer according to an embodiment of the present invention as a function of etching exposure time.

FIG. 12 is a graph illustrating actual distances of a conductive anti-reflection structure according to an embodiment of the present invention as a function of etching exposure time.

FIG. 13 illustrates a duplex structure of transparent or conductive substrates according to an embodiment of the present invention.

FIG. 14 is a flowchart illustrating a method for manufacturing a transparent or conductive substrate according to an embodiment of the present invention.

FIG. 15 illustrates a method for manufacturing a transparent or conductive substrate according to an embodiment of the present invention.

FIG. 16 is a graph illustrating improved degree in the transmittance of an anti-reflection layer according to an embodiment of the present invention.

FIG. 17 is a flowchart illustrating a method for manufacturing a transparent or conductive substrate according to another embodiment of the present invention.

FIG. 18 illustrates a method method for manufacturing a transparent or conductive substrate according to another embodiment of the present invention.

FIG. 19 is a graph illustrating improved degree in the transmittance of a conductive anti-reflection layer according to an embodiment of the present invention.

FIG. 20 is a flowchart illustrating a method for manufacturing a duplex structure of transparent or conductive substrates according to an embodiment of the present invention.

FIG. 21 illustrates a method for manufacturing a duplex structure of transparent or conductive substrates according to an embodiment of the present invention.

FIG. 22 is a graph illustrating improved degree in the transmittance of a duplex structure of transparent or conductive substrates according to an embodiment of the present invention.

### DESCRIPTION OF THE EXEMPLARY EMBODIMENTS

The present invention will be described in detail with reference to particular embodiments and it is to be appreciated that various changes and modifications may be made.

However, the exemplary embodiments disclosed in the present invention and the accompanying drawings do not limit the scope of the present invention. The scope of the present invention should be interpreted by the following claims and it should be interpreted that all spirits equivalent to the following claims fall within the scope of the present invention. Throughout the description of the present invention, when describing a certain technology is determined to evade the point of the present invention, the pertinent detailed description will be omitted.

While such terms as “first” and “second,” etc., may be used to describe various components, such components must not be limited to the above terms. The above terms are used only to distinguish one component from another.

The terms used in the description are intended to describe certain embodiments only, and shall by no means restrict the present invention. Unless clearly used otherwise, expressions in the singular number include a plural meaning. In the present description, an expression such as “comprising” or “consisting of” is intended to designate a characteristic, a number, a step, an operation, an element, a part or combinations thereof, and shall not be construed to preclude any presence or possibility of one or more other characteristics, numbers, steps, operations, elements, parts or combinations thereof.

Hereinafter, a transparent or conductive substrate and a manufacturing method thereof of the present invention will be described in detail with reference to the accompanying drawings, in which those components are rendered the same reference number that are the same or are in correspondence, regardless of the figure number, and redundant explanations are omitted.

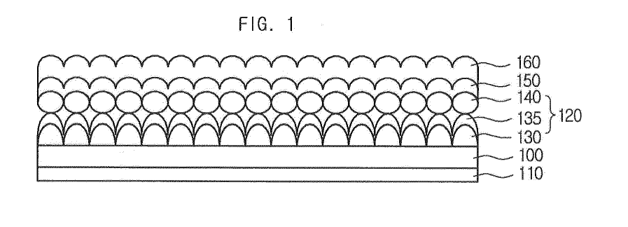

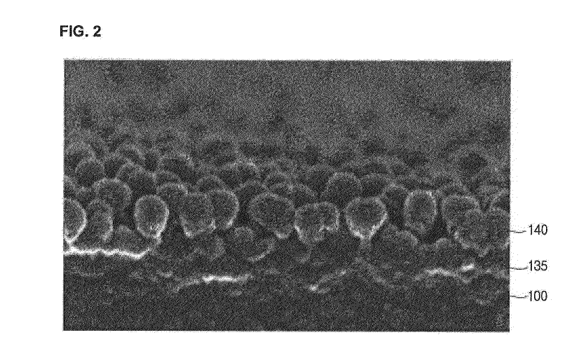

FIG. 1 is a diagram illustrating a transparent or conductive substrate according to an embodiment of the present invention and FIG. 2 illustrates an actual structure of an anti-reflection layer according to an embodiment of the present invention.

Referring to FIG. 1, the transparent or conductive substrate according to an embodiment of the present invention comprises a base substrate 100, a transparent electroconductive layer 110, an anti-reflection layer 120, a continuous thin layer 150 and a fingerprint prevention layer 160.

The transparent electroconductive layer 110 is a layer formed by depositing a transparent electroconductive material on a first side of the base substrate 100.

A transparent electroconductive material forming the transparent electroconductive layer 110 may be an oxide of Zn, Cd, In, Ga, Sn and Ti or a combination thereof. Examples of commonly used transparent electroconductive layer 110 include an indium tin oxide (ITO), indium zinc oxide (IZO), aluminum zinc oxide (AZO), gallium zinc oxide (GZO) and the like. At least two of those oxides may be formed in multi-layers.

Electroconductivity of the transparent electroconductive layer 110 is enhanced with increasing in the thickness thereof but light transmittance is decreased.

The transparent electroconductive layer 110 of the transparent or conductive substrate according to an embodiment of the present invention can be formed to have a thickness of 10 nm to 500 nm to use as a transparent or conductive substrate according to an embodiment of the present invention as displayers or transparent electrodes of solar cells.

The lower sheet resistance of the transparent electroconductive layer 110 means that electroconductivity of the transparent or conductive substrate becomes better. The sheet resistance of the transparent electroconductive layer 110 can be controlled to have 10Ω/□ to 200Ω/□ to use the transparent or conductive substrate according to an embodiment of the present invention as displayers or transparent electrodes of solar cells.

The anti-reflection layer 120 is formed on a second side of the base substrate 100 and comprises a plurality of spine-type structures 130 and anti-reflection structures 140.

Referring to FIG. 2, the anti-reflection layer 120 may further comprise a continuous layer 135 which is continuously formed between the plurality of spine-type structures 130 and the anti-reflection structures 140 by depositing an inorganic material on the plurality of spine-type structures 130.

The plurality of spine-type structures 130 are spine-shaped structure formed on the second side of the base substrate 100 by using a dry etching method.

The anti-reflection structure 140 is structure formed on each spine-type structure 130 by depositing inorganic particles on the plurality of spine-type structures 130 formed on the second side of the base substrate 100 using a dry etching method.

The inorganic particles forming the anti-reflection structure 140 may comprise at least one of metal oxides and metal nitrides of Al, Ba, Be, Ca, Cr, Cu, Cd, Dy, Ga, Ge, Hf, In, Lu, Mg, Mo, Ni, Rb, Sc, Si, Sn, Ta, Te, Ti, W, Zn, Zr, and Yb, oxynitrides (AlON, SiON) and magnesium fluoride. The anti-reflection layer 120 formed with the inorganic particles is able to prevent light reflection to improve light transmittance.

The continuous thin layer 150 is a layer having continuous side to improve physical properties such as intensity, hardness, durability and the like of the transparent or conductive substrate.

The continuous thin layer 150 may be formed on the anti-reflection layer 120. Furthermore, the continuous thin layer 150 may be formed to have a thickness of 5 nm to 100 nm to control optical properties.

The fingerprint prevention layer 160 is a layer having water repellency to prevent from water absorbing into the substrate when the substrate gets wet with water and an anti-fingerprint property to prevent fingerprints of users.

The fingerprint prevention layer 160 may be formed on the anti-reflection layer 120 or the continuous thin layer 150.

The fingerprint prevention layer 160 may be formed by depositing at least one selected from cyclomethicone (C₈H₂₄Si₄O₄), hexamethyldisiloxane(HMDSO), octamethylcyclotetrasiloxane(OMCTS), 2-fluoro-6-methoxybenzaldehyde, 3-fluoro-4 methoxybenzaldehyde, 4-fluoro-3-methoxybenzaldehyde, 5-fluoro-2-methoxybenzaldehyde, 2-fluoro-6-methoxyphenol, 4-fluoro-2-methoxyphenol and 5-fluoro-3-methoxysalicylaldehyde.

The fingerprint prevention layer 160 may be formed by comprising at least one of a methyl group(CH3) and a fluorocarbon group (CF).

Transmittance of the transparent or conductive substrate is controlled depending on diameter and arrangement distance of the anti-reflection structure 140 included in the anti-reflection layer 120. The diameter of the anti-reflection structure 140 can be controlled by adjusting processing conditions and time while the anti-reflection structure 140 is formed. The arrangement distance of the anti-reflection structure 140 can be controlled by adjusting distance of the plurality of spine-type structures 130 on which the anti-reflection structure 140 is to be formed.

The distance of the plurality of spine-type structures 130 can be controlled by adjusting plasma power or etching exposure time. The etching exposure time means the time to etch the base substrate 100 by exposing the base substrate 100 under plasma.

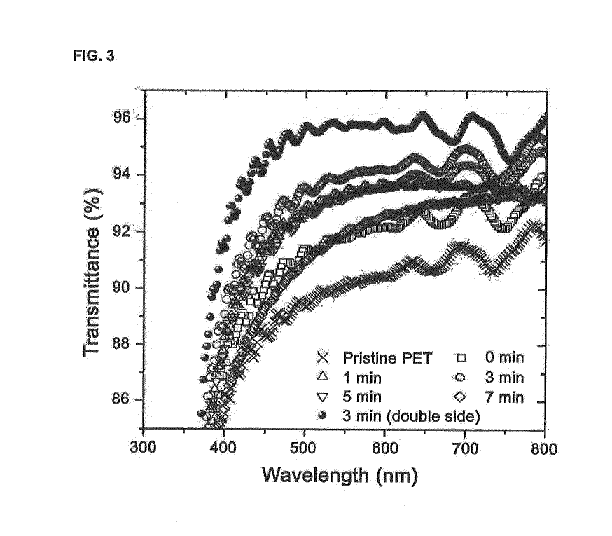

FIG. 3 is a graph illustrating transmittances of an anti-reflection layer according to an embodiment of the present invention as a function of etching exposure time. Referring to FIG. 3, transmittance of the transparent or conductive substrate shows the maximum value when the etching exposure time is about 3 min. When the plasma exposure time is 7 min or longer, it shows similar transmittance to that when it is not exposed.

Therefore, it is appropriate to control the etching exposure time of the base substrate 100 to be less than 7 min in order to form the plurality of spine-type structures 130 provided according to an embodiment of the present invention.

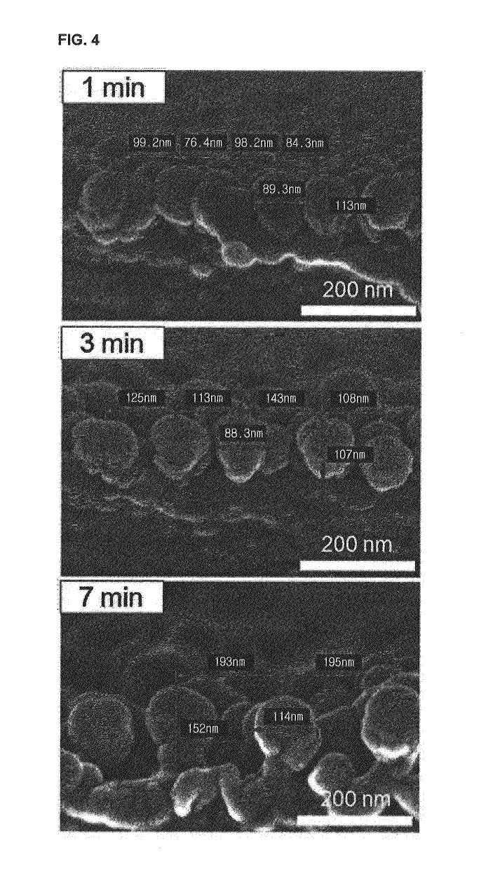

FIG. 4 is a graph illustrating actual distances of an anti-reflection structure according to an embodiment of the present invention as a function of etching exposure time. The distances of the anti-reflection structure 140 are determined at 1 min, 3 min, and 7 min of the etching exposure time as shown in Table 1.

TABLE 1

| | Etching exposure time | | |
|---|---|---|---|
| | 1 Min | 3 Min | 7 Min |
| Distance of the anti- | 76.4 nm-99.2 nm | 108 nm-143 nm | 193 nm-195 nm |
| reflection structure | | | |

Experiments were performed using Ar plasma with the intensity of 200 W(1.1 W/cm²) at RF frequency 13.56 MHz. It was determined when 3.1×10¹⁷ ions with energy of 102 eV is delivered to an area of 1 cm×1 cm of the base substrate 100 per minute.

Referring to FIG. 4, when the etching exposure time is controlled to be less than 7 min at the same plasma power, it is noted that the anti-reflection structure 140 is arranged at intervals of 200 nm or less. It is appropriate that the anti-reflection structure 140 be arranged at intervals of 200 nm or less in order to increase transmittance and prevent light reflection.

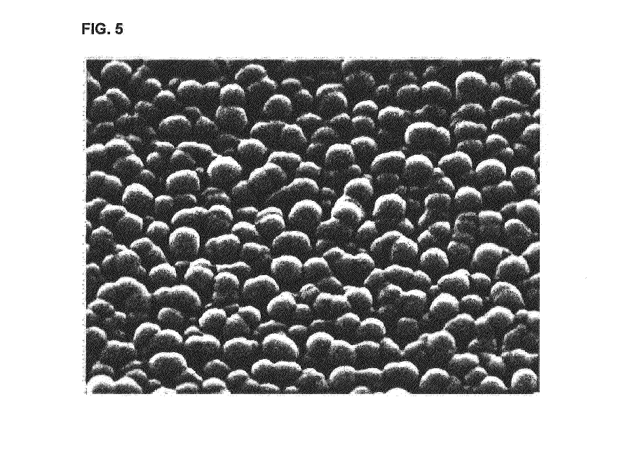

FIG. 5 illustrates an anti-reflection structure arranged adjacent to each other according to an embodiment of the present invention. As shown in FIG. 5, when the anti-reflection structure 140 is arranged adjacent to each other, optical properties of the anti-reflection layer 120 increases, compared to when it is not arranged adjacent to each other.

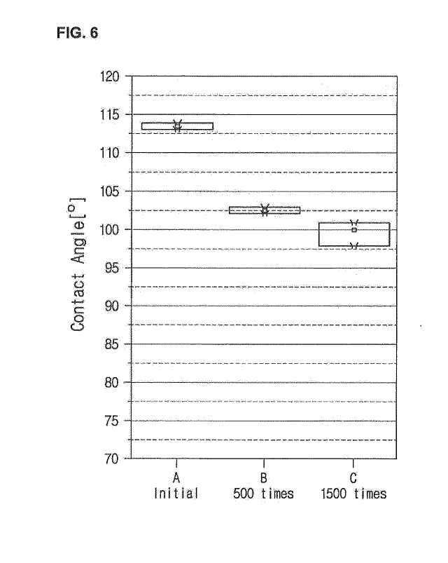

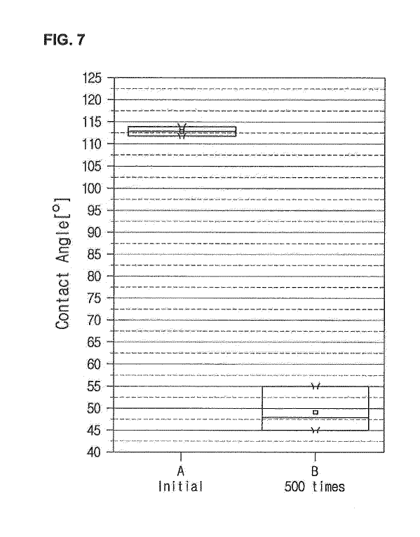

FIG. 6 illustrates durabilities of a transparent or conductive substrate according to an embodiment of the present invention. FIG. 7 illustrates durabilities of a conventional transparent or conductive substrate. When FIG. 6 and FIG. 7 are compared, when the anti-reflection structure 140 is arranged adjacent to each other, physical properties of the anti-reflection layer 120 are also increased, compared to when it is not arranged adjacent to each other.

The transparent or conductive substrate, in which the anti-reflection structure 140 is arranged adjacent to each other, is assigned as an experimental group and a substrate comprising a coating layer continuously formed without having the anti-reflection structure 140 is assigned as a control group. FIG. 6 and FIG. 7 show reliabilities from mar resistance test determined using a rubbing tester. The test was determined using a typing eraser (diameter ¼ in) as a rubber under a load of 500 gram, test speed of 40 times/min and number of tests of 1500 times. The result was analyzed by determining contact angle of H₂O before and after the rubbing test of each of the anti-reflection layer 120 and the coating layer to determine water repellency.

As shown in FIG. 6, the anti-reflection layer 120 including the anti-reflection structure 140 arranged adjacent to each other has less deviation of H₂O contact angle after the rubbing test, compared to the coating later in FIG. 7. It is thus noted that physical properties such as intensity and durability of the anti-reflection layer 120 are better than those of the coating layer.

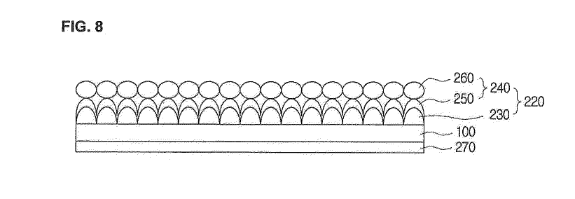

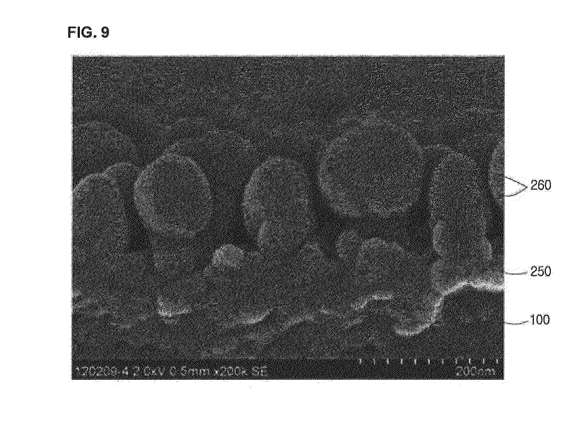

FIG. 8 illustrates a transparent or conductive substrate according to another embodiment of the present invention. FIG. 9 illustrates an acture structure of a conductive anti-reflection layer according to an embodiment of the present invention.

Referring to FIG. 8, the transparent or conductive substrate according to an embodiment of the present invention comprises a base substrate 100, a conductive anti-reflection layer 220 and a protection layer 270.

The base substrate 100 is a polymer substrate composed of a light transmittable material which is identical to that described with reference to FIG. 1.

The conductive anti-reflection layer 220 is formed on a first side of the base substrate 100 and comprises a plurality of spine-type structures 230 and an anti-reflection transparent electroconductive layer 240.

The plurality of spine-type structures 230 are structures formed on the first side of the base substrate 100 by using a dry etching method.

Referring to FIG. 9, the anti-reflection transparent electroconductive layer 240 may comprise a continuous conducting layer 250 continuously formed to the plurality of spine-type structures and a conductive anti-reflection structure 260 to prevent the reflection of light.

A transparent electroconductive material forming the anti-reflection transparent electroconductive layer 240 may be an oxide comprising at least one of Zn, Cd, In, Ga, Sn and Ti. The commonly used anti-reflection transparent electroconductive layer 240 may be indium tin oxide (ITO), indium zinc oxide (IZO), aluminum zinc oxide (AZO), gallium zinc oxide (GZO) or may be formed in a multilayer structure of 2 or more oxides.

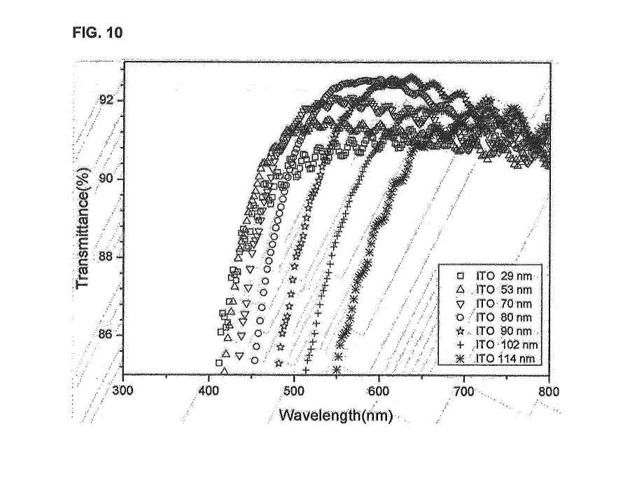

FIG. 10 is a graph illustrating transmittances of an anti-reflection transparent electroconductive layer according to an embodiment of the present invention as a function of thickness. Referring to FIG. 10, the visible ray region, where the transmittance of the transparent or conductive substrate is shown, moves to longer wavelengths as the thickness of the anti-reflection transparent electroconductive layer 240 increases. When the thickness of the anti-reflection transparent electroconductive layer 240 is 110 nm or higher, visible light with 600 nm or higher wavelength can be only transmitted. When the thickness of the anti-reflection transparent electroconductive layer 240 is 114 nm or higher, the transparent or conductive substrate may lose its transmittance property due to very limited transmitable visible light.

Therefore, the anti-reflection transparent electroconductive layer 240 may be formed in the thickness of from 30 nm to 110 nm. The transparent or conductive substrate comprising the anti-reflection transparent electroconductive layer 240 formed with such a thickness can be used for touch screens.

Sheet resistance of the anti-reflection transparent electroconductive layer 240 may be controlled to be from 100Ω/□ to 1000Ω/□ in order to use the transparent or conductive substrate for touch screens.

Referring FIG. 8 again, the continuous conducting layer 250 is a layer continuously formed with a transparent electroconductive material between the plurality of spine-type structures 230 and the conductive anti-reflection structure 260. The continuous conducting layer 250 provides conductivity to the entire anti-reflection transparent electroconductive layer 240.

The conductive anti-reflection structure 260 is the structure formed on the upper side of the plurality of spine-type structures 230 and the continuous conducting layer 250.

The protection layer 270 prevents contamination of oxygen, water or the like to the base substrate 100 or penetration of foreign materials which may cause defects of the transparent or conductive substrate. The protection layer 270 also enhances hardness of the transparent or conductive substrate and protects the transparent or conductive substrate. The protection layer 270 may be formed on a second side of the base substrate 100.

Optical properties of the transparent or conductive substrate are controlled by diameter and arrangement distance of the conductive anti-reflection structure 260 included in the conductive anti-reflection layer 220. The diameter of the conductive anti-reflection structure 260 can be controlled with processing conditions and time during the formation of the conductive anti-reflection structure 260. On the other hand, the arrangement distance of the conductive anti-reflection structure 260 can be controlled with distance between the plurality of spine-type structures 230 on which the conductive anti-reflection structure 260 is formed.

The distance of the plurality of spine-type structures 230 can be controlled with plasma power or etching exposure time. The etching exposure time is time to etch the base substrate 100 by exposing the base substrate 100 under plasma.

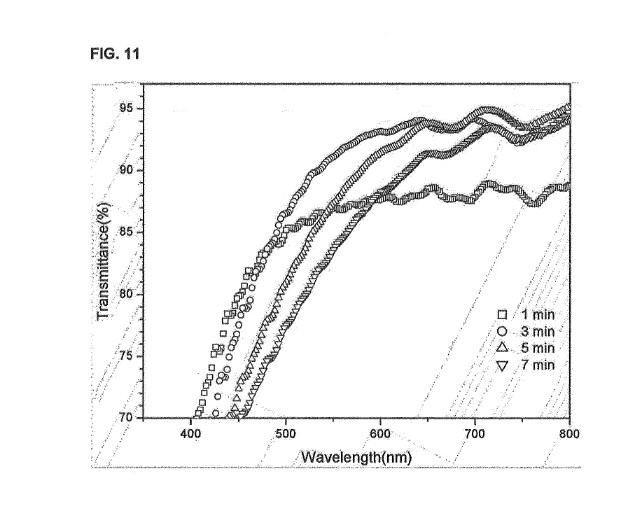

FIG. 11 is a graph illustrating transmittances of a conductive anti-reflection layer according to an embodiment of the present invention as a function of etching exposure time. Referring to FIG. 11, visible light region, where the transmittance of the transparent or conductive substrate is shown, is the widest when the etching exposure time is 3 min, while it is the least when the etching exposure time is 7 min. When the etching exposure time is 7 min or longer, the transmittance is shown only at long wavelength of about 650 nm or higher.

Therefore, it is appreciated that the etching exposure time of the base substrate 100 be less than 7 min to form the plurality of spine-type structures 230 provided according to an embodiment of the present invention.

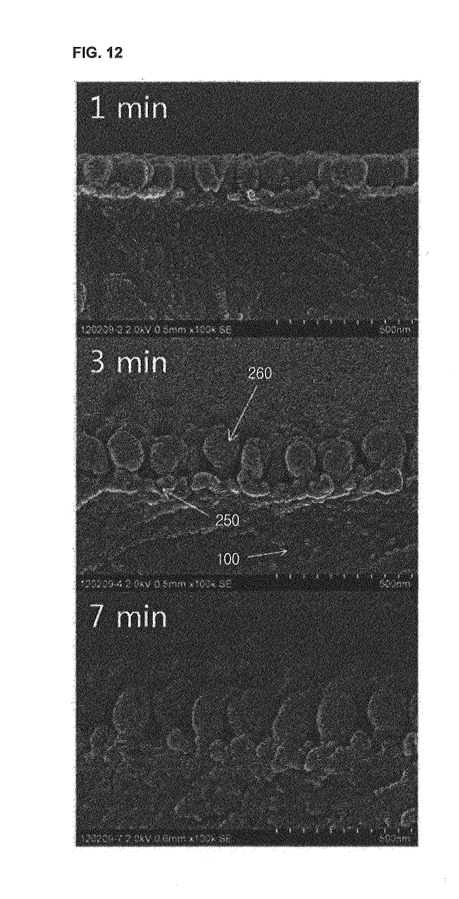

FIG. 12 is a graph illustrating actual distances of a conductive anti-reflection structure according to an embodiment of the present invention as a function of etching exposure time. Referring to FIG. 12, it is noted that when the etching exposure time is set for 1 min, 3 min and 7 min, the distances of the conductive anti-reflection structure 260 are different.

The distance of the conductive anti-reflection structure 260 can be controlled by controlling the etching exposure time. When the distance of the conductive anti-reflection structure 260 is changed, density of the anti-reflection transparent electroconductive layer 240 may be changed and thus the refractive index of the anti-reflection transparent electroconductive layer 240 may be changed. Accordingly, the transmittance of the transparent or conductive substrate can be controlled with the distance of the conductive anti-reflection structure 260.

The distance of the conductive anti-reflection structure 260 may be 200 nm or less to increase the optical transmittance of the transparent or conductive substrate. The conductive anti-reflection structure 260 may be arranged to adjacent to one another. When the conductive anti-reflection structure 260 is arranged to adjacent to one another, optical properties of the conductive anti-reflection layer 220 may be improved, compared with when it is not arranged to adjacent to one another.

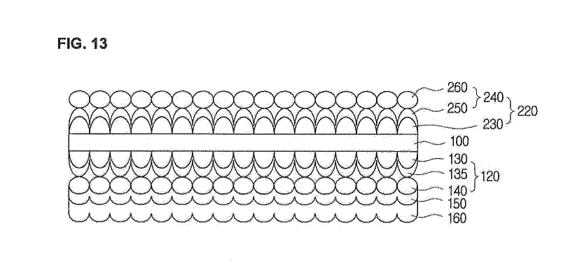

FIG. 13 illustrates a duplex structure of transparent or conductive substrates according to an embodiment of the present invention. Referring to FIG. 13, a transparent or conductive substrate according to another embodiment of the present invention may comprise a base substrate 100, an anti-reflection layer 120, a continuous thin layer 150, a fingerprint prevention layer 160 and a conductive anti-reflection layer 220.

The base substrate 100, the anti--reflection layer 120, the continuous thin layer 150 and the fingerprint prevention layer 160 are identical to those described with reference to FIG. 1. The conductive anti-reflection layer 220 is identical to that described with reference to FIG. 2.

Hereinafter, a method for manufacturing the above-described transparent or conductive substrate will be explained.

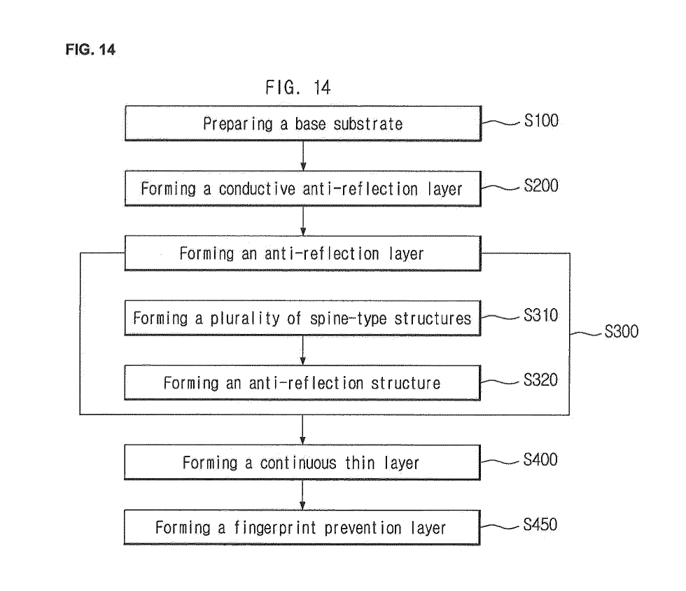

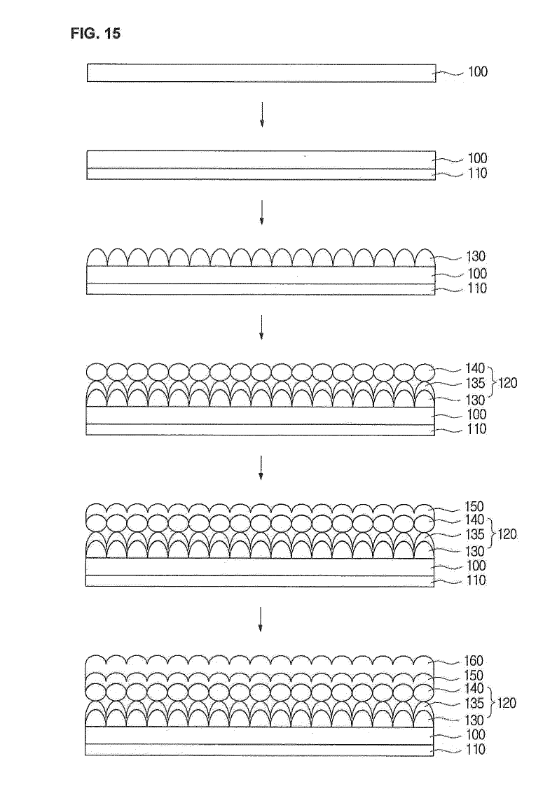

FIG. 14 is a flowchart illustrating a method for manufacturing a transparent or conductive substrate according to an embodiment of the present invention. FIG. 15 illustrates a method for manufacturing a transparent or conductive substrate according to an embodiment of the present invention.

Referring to FIG. 14 and FIG. 15, a method for manufacturing a transparent or conductive substrate according to an embodiment of the present invention comprises preparing a base substrate (S100); forming a conductive anti-reflection layer (S200); forming an anti-reflection layer 120 (S300); forming a continuous thin layer 150 (S400); and forming a fingerprint prevention layer 160 (S450).

The step of preparing a base substrate in S100 is preparing a base substrate composed of a polymer material which is capable of light transmission.

The step of forming a transparent electroconductive layer 110 in S200 is step of depositing a transparent electroconductive material on the first side of the base substrate 100 to form the transparent electroconductive layer 110 continuously.

The method for forming the transparent electroconductive layer 110 by depositing a transparent electroconductive material may be a sputtering method as follows.

The base substrate 100 is first placed in a vacuum chamber. A vacuum level inside the vacuum chamber is maintained to be 2×10⁻⁵ torr by using a low vacuum pump and a high vacuum pump. Ar operation gas is then charged and an operation vacuum level is reached to 2×10⁻³ torr. Power is provided to a plasma generator connected to a sputtering target to which a transparent electroconductive material is attached to generate plasma so that the transparent electroconductive material is deposited on the first side of the base substrate 100.

Detailed conditions for forming the transparent electroconductive layer 110 by depositing the transparent electroconductive material are as follows:
base substrate: PET thickness 125, transmittance 90%
base vacuum level: 2×10⁻⁵ torr
oxide transparent electroconductive layer coating
sputtering target: ITO

operation gas: Ar⁺ (O₂)
operation vacuum level: 2×10⁻³ torr
RF power: 200 W (target area 400 cm²).

When the transparent electroconductive layer 110 is formed by the method described above, the transparent or conductive substrate may have electroconductivity.

The step of forming an anti-reflection layer 120 in S300 comprises forming a plurality of spine-type structures 130 of S310 and forming an anti-reflection structure 140 of S320.

The step of forming a plurality of spine-type structures 130 in S310 is forming a plurality of spine-type structures 130 on the second side of the base substrate 100 by using a dry etching method.

The dry etching method may control to form a plurality of spine-type structures 130 more precisely and accurately compared to a wet etching method.

The dry etching method may be a plasma etching method. A material used for the plasma etching method may comprise at least one gas chosen from Ar, O₂, H₂, He and N₂. When the base substrate 100 is exposed under the plasma formed by comprising at least one gas chosen from Ar, O₂, H₂, He and N₂, the second side of the base substrate 100 is etched to form a plurality of spine-type structures 130.

The step of forming an anti-reflection structure 140 in S320 is forming an anti-reflection structure 140 on each spine-type structure 130 by depositing inorganic particles on the plurality of spine-type structures 130 which are formed on the second side of the base substrate 100.

A continuous layer 135 is formed by depositing inorganic particles uniformly on the valley between the plurality of spine-type structures 130 at the initial deposition.

Shadow effect may be caused as the time for depositing inorganic particles increases. The inorganic particles, which reach to the second side of the base substrate 100, are covered with the continuous layer 135 formed on the upper part of the plurality of spine-type structures 130 so that the inorganic particles cannot reach the valley between the plurality of spine-type structures 130. Thus, the inorganic particles can be deposited only on the continuous layer 135 formed on the plurality of spine-type structures 130 to from the anti-reflection structure 140 having unit particle structure. Here, the anti-reflection structure 140 may be formed in a spherical shape.

A method for depositing inorganic particles may be a chemical vapor deposition (CVD) or a physical vapor deposition (PVD).

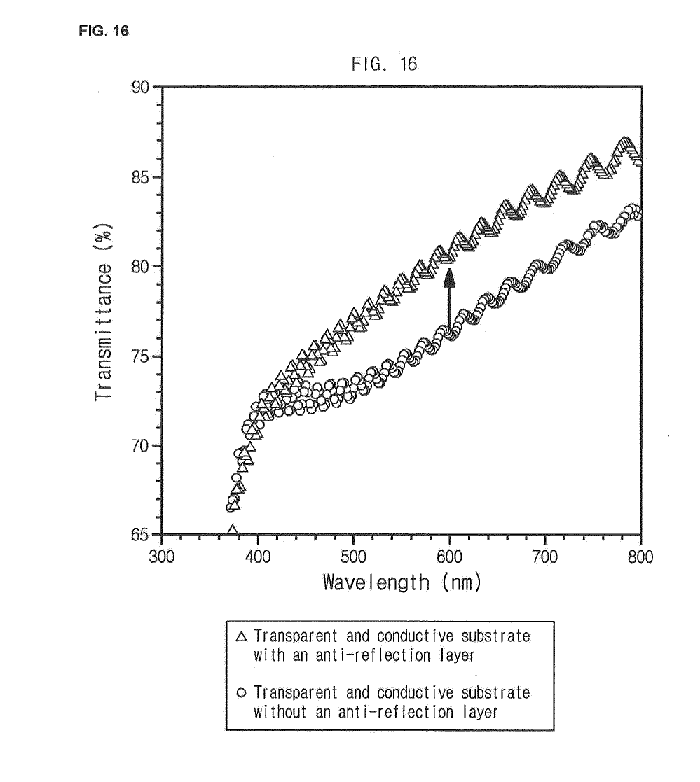

FIG. 16 is a graph illustrating improved degree in the transmittance of an anti-reflection layer according to an embodiment of the present invention. As shown in FIG. 16, the transparent or conductive substrate with the anti-reflection layer 120 shows greater transmittance than that without the anti-reflection layer 120. The transparent electroconductive layer 110 in FIG. 16 is formed by using ITO and the anti-reflection layer 120 is formed by using SiOx to have 90 nm thickness.

Referring to FIG. 14 and FIG. 15 again, the step of forming a continuous thin layer 150 of S400 is forming a continuous thin layer 150 on the anti-reflection layer 120.

The continuous thin layer 150 may be formed by depositing inorganic particles. A method for depositing inorganic particles may be a chemical vapor deposition (CVD) or a physical vapor deposition (PVD).

The inorganic particles forming the continuous thin layer 150 may be identical to those used for forming the anti-reflection structure 140. When the continuous thin layer 150 is formed by using the same material used for forming the anti-reflection structure 140, it can facilitate to control optical properties such as refraction of light and reduce manufacturing processes.

The continuous thin layer 150 may be formed by a sol-gel method or a dipping method. Namely, the continuous thin layer 150 may be formed by coating liquid inorganic particles on the space between the anti-reflection structures 140.

The step of forming a fingerprint prevention layer 160 in S450 is forming a fingerprint prevention layer 160 providing water repellency and anti-fingerprint property to the continuous thin layer 150.

The fingerprint prevention layer 160 may be formed by using a dry coating method or a wet coating method. The dry coating method may be a chemical vapor deposition (CVO) or a physical vapor deposition (PVD).

According to another embodiment of the present invention, the fingerprint prevention layer 160 may be formed on the anti-reflection layer 120, not on the continuous thin layer 150.

As described above, the transparent or conductive substrate having excellent electrical properties, optical properties and anti-fingerprint properties may be provided by forming continuously the transparent electroconductive layer 110 on the first side of the base substrate 100 and forming the anti-reflection layer 120, the continuous thin layer 150 and the fingerprint prevention layer 160 on the second side of the base substrate 100.

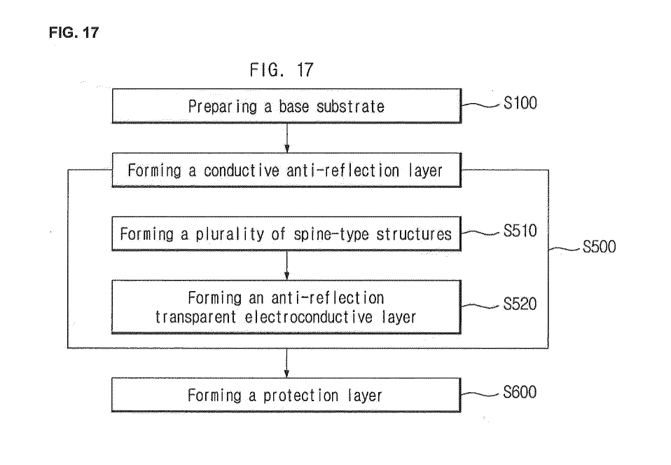

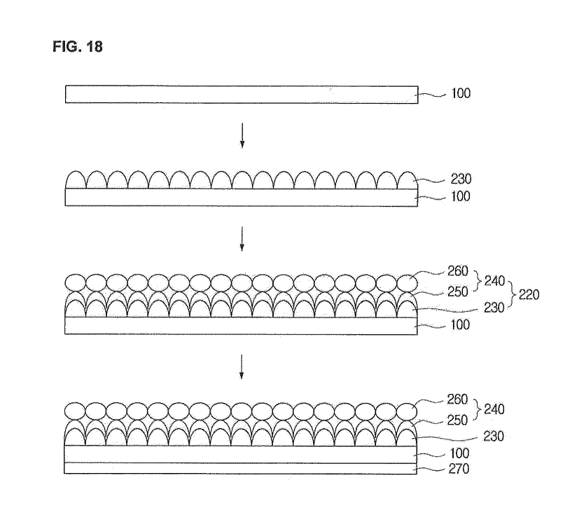

FIG. 17 is a flowchart illustrating a method for manufacturing a transparent or conductive substrate according to another embodiment of the present invention. FIG. 18 illustrates a method method for manufacturing a transparent or conductive substrate according to another embodiment of the present invention.

Referring to FIG. 17 and FIG. 18, a method for manufacturing a transparent or conductive substrate comprises preparing a base substrate 100 (S100); forming a conductive anti-reflection layer 220 (S500); and forming a protection layer 270 (S600).

The step of preparing a base substrate 100 in S100 is preparing a base substrate composed of a material which is capable of light transmission.

The step of forming a conductive anti-reflection layer 220 in S500 comprises forming a plurality of spine-type structures 230 of S510 and forming art anti-reflection transparent electroconductive layer 240 of S520.

The step of forming a plurality of spine-type structures 230 in S510 is forming a plurality of spine-type structures 230 on the first side of the base substrate 100 by using a dry etching method.

The dry etching method may control to form a plurality of pine-type structures 230 more precisely and accurately. The dry etching method may be an ion-beam etching method used in a sputtering process as follows.

The base substrate 100 is first placed in a vacuum chamber. A vacuum level inside the vacuum chamber is maintained to be 2×10⁻⁵ torr by using a low vacuum pump and a high vacuum pump. Operation of ion-beam device eliminates adsorbate gas particles and contaminants existing on the base substrate 100. The ion-beam device can be operated using an end-hall method by generating plasma through thermionic emission from filament and accelerating emission of ions existing in the plasma.

More particularly, the ion-beam etching method can be performed by maintaining a vacuum level to be 5×10⁻⁵ torr to 5×10⁻⁴ torr by charging Ar mixture gas inside the vacuum chamber and setting a filament power for about 400 W(20 A×20V), an ion-beam power of 180 W(2 A×90V) within 10 min or less.

The dry etching method may be a plasma etching method. A material used for the plasma etching method may comprise at least one gas chosen from Ar, O₂, H₂, He and N₂. When the base substrate 100 is exposed under the plasma formed by comprising at least one gas chosen from Ar, O₂, H₂, He and N₂, the first side of the base substrate 100 is etched to form a plurality of spine-type structures 230. When the plurality of spine-type structures 230 are formed by using the plasma etching method, it is formed in a different chamber from the chamber in which an anti-reflection transparent electroconductive layer 240 to be described later is formed.

The step of forming an anti-reflection transparent electroconductive layer 240 in S520 is forming a continuous conducting layer 250 and a conductive anti-reflection structure 260 which are formed continuously to the plurality of spine-type structures 230 by depositing a transparent electroconductive material on the plurality of spine-type structures 230 which is formed on the first side of the base substrate 100.

The continuous conducting layer 250 is formed under the conductive anti-reflection structure 260 to provide conductivity to the entire anti-reflection transparent electroconductive layer 240, Here, the continuous conducting layer 260 and the conductive anti-reflection structure 260 may be formed at the same time.

According to an embodiment of the present invention, the method for forming the anti-reflection transparent electroconductive layer 240 by depositing a transparent electroconductive material may be a sputtering method as follows.

The base substrate 100 is first placed in a vacuum chamber. A vacuum level inside the vacuum chamber is maintained to be 2×10⁻⁵ torr by using a low vacuum pump and a high vacuum pump. Ar operation gas is then charged and an operation vacuum level is reached to 2×10⁻³ torr. Power is provided to a plasma generator connected to a sputtering target to which a transparent electroconductive material is attached to generate plasma so that the transparent electroconductive material is deposited on the first side of the base substrate 100.

Detailed conditions for forming the anti-reflection transparent electroconductive layer 240 by depositing the transparent electroconductive material are as follows:
Base substrate: PET thickness 125, transmittance 90%
Base vacuum level: 2×10⁻⁵ torr
Oxide transparent electroconductive layer coating
sputtering target: ITO
Operation gas: Ar⁺ (O₂)
Operation vacuum level: 2×10⁻³ torr
RF power: 200 W (target area 400 cm²).

The continuous conducting layer 250 is formed by depositing a transparent electroconductive material uniformly on the plurality of spine-type structures 230 at the initial deposition of the transparent electroconductive material.

Shadow effect may be caused as the time for depositing transparent electroconductive material increases. The transparent electroconductive material, which reaches to the base substrate 100, is covered with the plurality of spine-type structures 230 and the continuous conducting layer 250 formed on the upper part of the plurality of spine-type structures 230 so that the transparent electroconductive material cannot reach the valley between the plurality of spine-type structures 230. Thus, the transparent electroconductive material can be deposited only on the continuous conducting layer 250 formed on the plurality of spine-type structures 230 to from the conductive anti-reflection structure 260. Here, the conductive anti-reflection structure 260 may be formed in a spherical shape.

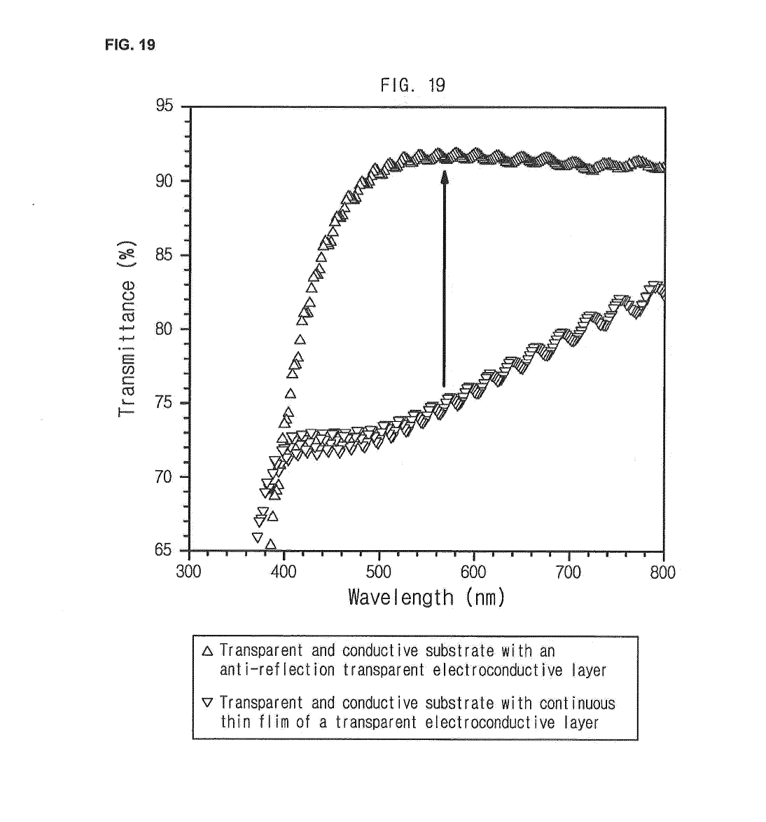

FIG. 19 is a graph illustrating improved degree in the transmittance of a conductive anti-reflection layer according to an embodiment of the present invention. As shown in FIG. 19, when the anti-reflection transparent electroconductive layer 240 is formed on the base substrate 100, the transparent or conductive substrate can have improved optical transmittance due to increased light transmittance, compared to that when a continuous thin film is formed by having the same thickness of a transparent electroconductive material, The anti-reflection transparent electroconductive layer 240 in FIG. 19 is formed by using ITO to have 90 nm thickness.

Referring to FIG. 17 and FIG. 18 again, the step of forming a protection layer 270 in S600 is continuously forming a protection layer 270 on the second side of the base substrate 100 without any etching process to protect the base substrate 100 from the outside environment.

The protection layer 270 may be formed by depositing an oxide of Si, Al, Zn, Ti or a mixture thereof using a chemical vapor deposition (CVD) or a physical vapor deposition (PVD).

As described above, when a plurality of spine-type structures 230 are formed on the first side of the polymer base substrate 100 and the anti-reflection transparent electroconductive layer 240 comprising the continuous conducting layer 250 and the conductive anti-reflection structure 260 is formed by depositing a transparent electroconductive material, it can facilitate to control the conductive anti-reflection layer 220 to provide a transparent or conductive substrate having improved optical properties and having a protection layer on the second side of the base substrate 100 to protect the base substrate 100.

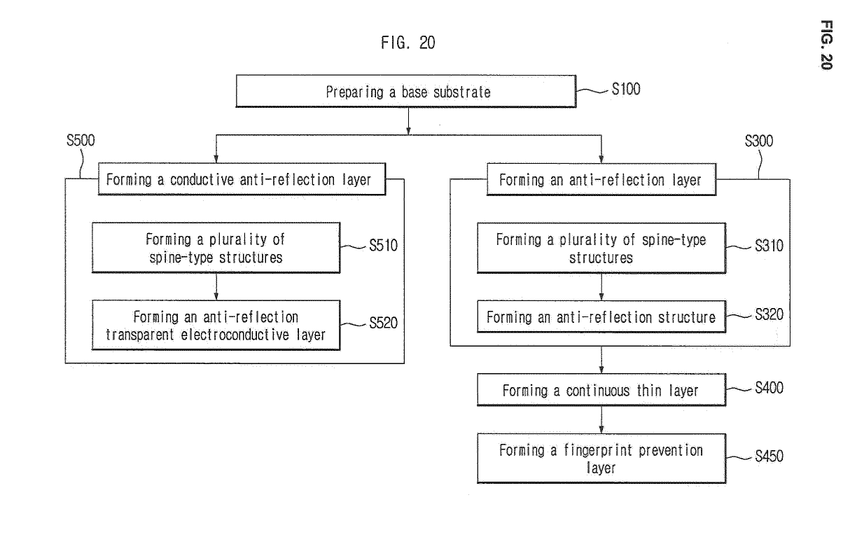

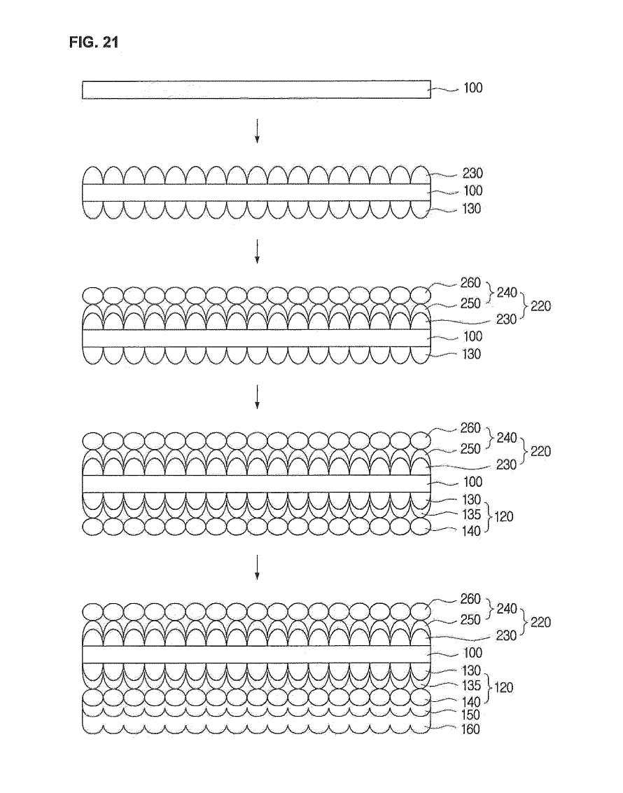

FIG. 20 is a flowchart illustrating a method for manufacturing a duplex structure of transparent or conductive substrates according to an embodiment of the present invention. FIG. 21 illustrates a method for manufacturing a duplex structure of transparent or conductive substrates according to an embodiment of the present invention.

Referring to FIG. 20 and FIG. 21, a method for manufacturing a transparent or conductive substrate according to an embodiment of the present invention comprises preparing a base substrate 100 (S100); forming an anti-reflection layer 120 (S300); forming a continuous thin layer 150 (S400); forming a fingerprint prevention layer 160 (S450); and a conductive anti-reflection layer 220 (S500).

The steps of preparing a base substrate 100 of S100, forming an anti-reflection layer 120 of S300, forming a continuous thin layer 150 of S400 and forming a fingerprint prevention layer 160 of S450 are identical to those described with reference to FIG. 14 and FIG. 15. The step of forming a conductive anti-reflection layer 220 of S500 is identical to that described with reference to FIG. 17 and FIG. 18.

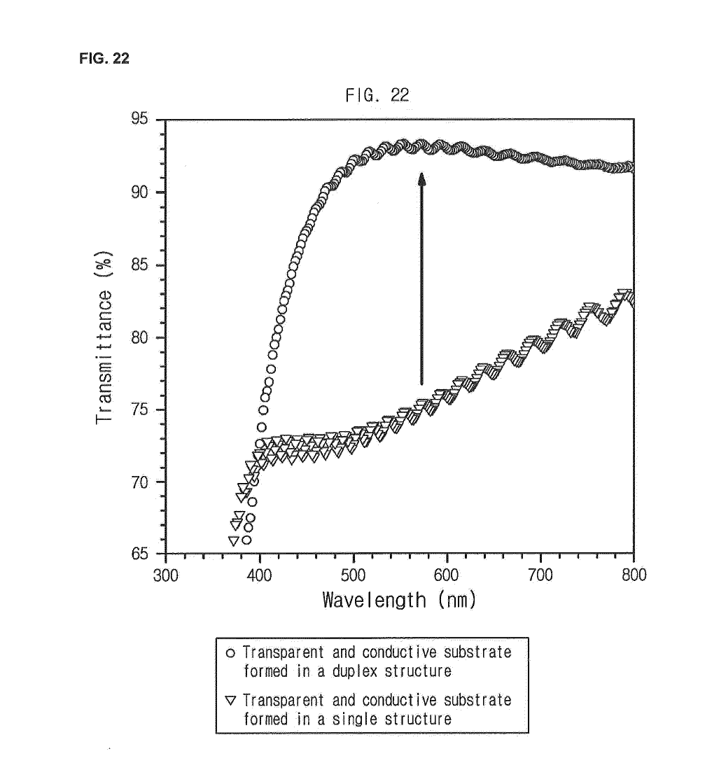

FIG. 22 is a graph illustrating improved degree in the transmittance of a duplex structure of transparent or conductive substrates according to an embodiment of the present invention. Referring to FIG. 22, when the conductive anti-reflection layer 220 and the anti-reflection layer 120 are formed on the base substrate in a duplex structure, the transmittance of the transparent or conductive substrate is much more improved, compared with the transparent or conductive substrate in a single structure. The transparent or conductive substrate formed in a duplex structure is compared with the transparent or conductive substrate formed in a continuous thin film by ITO to have 70 nm thickness which is a control group.

The spirit of the present invention has been described by way of example hereinabove, and the present invention may be variously modified, altered, and substituted by those skilled in the art to which the present invention pertains without departing from essential features of the present invention. Accordingly, the exemplary embodiments disclosed in the present invention and the accompanying drawings do not limit but describe the spirit of the present invention, and the scope of the present invention is not limited by the exemplary embodiments and accompanying drawings.

### DESCRIPTION OF REFERENCE NUMERALS

100: Base substrate
110: Transparent electro conductive layer
120: Anti-reflection layer
220: Conductive anti-reflection layer
130, 230: A plurality of spine-type structures
135: Continuous layer
140: Anti-reflection structure
240: Anti-reflection transparent electroconductive layer
250: Continuous conducting layer
260: Conductive anti-reflection structure
150: Continuous thin layer
160: Fingerprint prevention layer

1-64. (canceled)

65. A substrate comprising:
a base substrate;
a plurality of spine-type structures on the surface of the base substrate by using a dry etching method; and
a structure formed on the plurality of spine-type structures by depositing inorganic particles.

66. The substrate of claim 65, further comprising a continuous layer formed by depositing inorganic particles between the plurality of spine-type structures and the structure formed by depositing inorganic particles.

67. The substrate of claim 65, wherein the structure formed by depositing inorganic particles is formed to be adjacent to each other.

68. The substrate of claim 65, wherein the structure formed by depositing inorganic particles prevents light reflection and/or has conductivity.

69. The substrate of claim 65, wherein the base substrate comprises a reinforced coating layer.

70. The substrate of claim 65, wherein an arrangement interval of plurality of spine-type structures is adjusted by controlling etching exposure time.

71. The substrate of claim 65, further comprising a continuous thin layer on the structure formed by depositing inorganic particles.

72. The substrate of claim 71, further comprising a fingerprint prevention layer on the continuous thin layer.

73. The substrate of claim 65, further comprising a fingerprint prevention layer on the structure formed by depositing inorganic particles.

74. The substrate of claim 65, further comprising a protection layer on the other surface of the base substrate.

75. A method for manufacturing a substrate comprising:
preparing a base substrate;
forming a plurality of spine-type structures on the surface of the base substrate by using a dry etching method; and
forming a structure by depositing inorganic particles on the plurality of spine-type structures.

76. The method for manufacturing a substrate of claim 75, further comprising forming a continuous layer formed by depositing inorganic particles between the plurality of spine-type structures and the structure formed by depositing inorganic particles.

77. The method for manufacturing a substrate of claim 75, wherein the structure formed by depositing inorganic particles is formed to be adjacent to each other.

78. The method for manufacturing a substrate of claim 75, wherein the structure formed by depositing inorganic particles prevents light reflection and/or has conductivity.

79. The method for manufacturing a substrate of claim 75, wherein the base substrate comprises a reinforced coating layer.

80. The method for manufacturing a substrate of claim 75, wherein an arrangement interval of plurality of spine-type structures is adjusted by controlling etching exposure time.

81. The method for manufacturing a substrate of claim 75, further comprising forming a continuous thin layer on the structure formed by depositing inorganic particles.

82. The method for manufacturing a substrate of claim 81, further comprising forming a fingerprint prevention layer on the continuous thin layer.

83. The method for manufacturing a substrate of claim 75, further comprising forming a fingerprint prevention layer on the structure formed by depositing inorganic particles.

84. The method for manufacturing a substrate of claim 75, further comprising forming a protection layer on the other surface of the base substrate.
